(19) United States
(12) Patent Application Publication
(10) Pub. No.: US 2005/0012027 A1
(43) Pub. Date: Jan. 20, 2005

(54) Image sensor and method for packaging the same

(76) Inventors: Jackson Hsieh, Hsinchu Hsien (TW); Jichen Wu, Hsinchu Hsien (TW)

Correspondence Address: PRO-TECHTOR INTERNATIONAL, 20775 Norada Court, Saratoga, CA, 95070-3018, US

(21) Appl. No.: 10/621,991

(22) Filed: Jul. 16, 2003

(51) Int. Cl. H01L 27/00; H01L 31/00

(52) U.S. Cl. 250/208.1; 250/214.1

(57) ABSTRACT

An image sensor includes plural lower metal sheets, plural upper metal sheets stacked on the lower metal sheets, and an encapsulant for encapsulating the lower and upper metal sheets, wherein the upper surfaces of the upper metal sheets are exposed from the encapsulant, the lower surfaces of the lower metal sheets are exposed from the encapsulant, and the encapsulant is formed with a frame layer around the upper surfaces of the upper metal sheets to define a chamber together with the upper metal sheets. The image sensor further includes a photosensitive chip arranged within the chamber, plural wires for electrically connecting the chip to the upper surfaces of the upper metal sheets, and a transparent layer arranged on the frame layer to cover the chip.

### BACKGROUND OF THE INVENTION

1. Field of the Invention

The invention relates to an image sensor and a method for packaging the same, and more particularly to an image sensor and a method for packaging the same with increased product reliability and facilitated packaging processes.

2. Description of the Related Art

Referring to FIG. 1, which is a cross-sectional view showing an image sensor disclosed in a commonly-assigned, copending U.S. patent application Ser. No. 10/146,997, filed on May 15, 2002. The image sensor 1 includes a substrate 10, a frame layer 18, a photosensitive chip 22, a plurality of wires 24, and a transparent layer 27. The substrate 10 is composed of a plurality of metal sheets 12 arranged in an array. Each of the metal sheets 12 has a first board 14 and a second board 16 at different levels. The frame layer 18 is formed at a periphery and a bottom surface of the substrate 10 to form a chamber 20 together with the substrate 10. Top surfaces of the first boards 14 and bottom surfaces of the second boards 16 are exposed from the frame layer 18. The photosensitive chip 22 is arranged within the chamber 20 defined by the frame layer 18 and the substrate 10. The wires 24 electrically connect the top surfaces of the first boards 14 of the metal sheets 12 to the photosensitive chip 22. The transparent layer 26 is arranged on the frame layer 18 to cover the photosensitive chip 22.

However, the above-mentioned structure has the following drawbacks.

1. Since the metal sheets 12 are bent to form the first boards 14 and second boards 16 at different levels, the formed first boards 14 may be uneven. Therefore, the wires 24 cannot be conveniently bonded to the metal sheets 12, and the yield may be influenced.

2. Since the thickness of each of the second boards 16 of the metal sheets 12 is thinner (because each metal sheet 12 with greater thickness cannot be pressed during the manufacturing processes), the solder tin cannot climb to the lateral side of each metal sheet 12 during the SMT process. Therefore, the package body cannot be mounted to the printed circuit board with great stability.

### SUMMARY OF THE INVENTION

An object of the invention is to provide an image sensor with increased thickness of the combined metal sheets, and a method for packaging the same with improved package reliability.

Another object of the invention is to provide an image sensor and a method for packaging the same, wherein the solder tin may climb higher during the SMT process and the image sensor may be mounted to the printed circuit board with great stability.

Still another object of the invention is to provide an image sensor and a method for packaging the same, wherein the wire bonding process may be easily performed and the product yield may be increased.

To achieve the above-mentioned objects, the invention provides an image sensor to be electrically connected to a printed circuit board. The image sensor includes a plurality of lower metal sheets arranged in an array, a plurality of upper metal sheets arranged in an array, an encapsulant for encapsulating the lower metal sheets and the upper metal sheets, a photosensitive chip, a plurality of wires, and a transparent layer. Each of the lower metal sheets has an upper surface and a lower surface. Each of the upper metal sheets has an upper surface and a lower surface. The lower surfaces of the upper metal sheets are stacked on the upper surfaces of the lower metal sheets. The upper surfaces of the upper metal sheets are exposed from the encapsulant, and the lower surfaces of the lower metal sheets are exposed from the encapsulant and electrically connected to the printed circuit board. The encapsulant is formed with a frame layer around the upper surfaces of the upper metal sheets to define a chamber together with the upper metal sheets. The photosensitive chip is arranged within the chamber. The wires electrically connect the photosensitive chip to the upper surfaces of the upper metal sheets. The transparent layer is arranged on the frame layer of the encapsulant to cover the photosensitive chip.

### BRIEF DESCRIPTION OF THE DRAWINGS

FIG. 1 is a cross-sectional view showing an image sensor disclosed in a commonly-assigned, copending U.S. patent application Ser. No. 10/146,997, filed on May 15, 2002.

FIG. 2 is a cross-sectional view showing an image sensor of the invention.

FIG. 3 is a first schematic illustration showing a method for packaging the image sensor of the invention.

FIG. 4 is a second schematic illustration showing the method for packaging the image sensor of the invention.

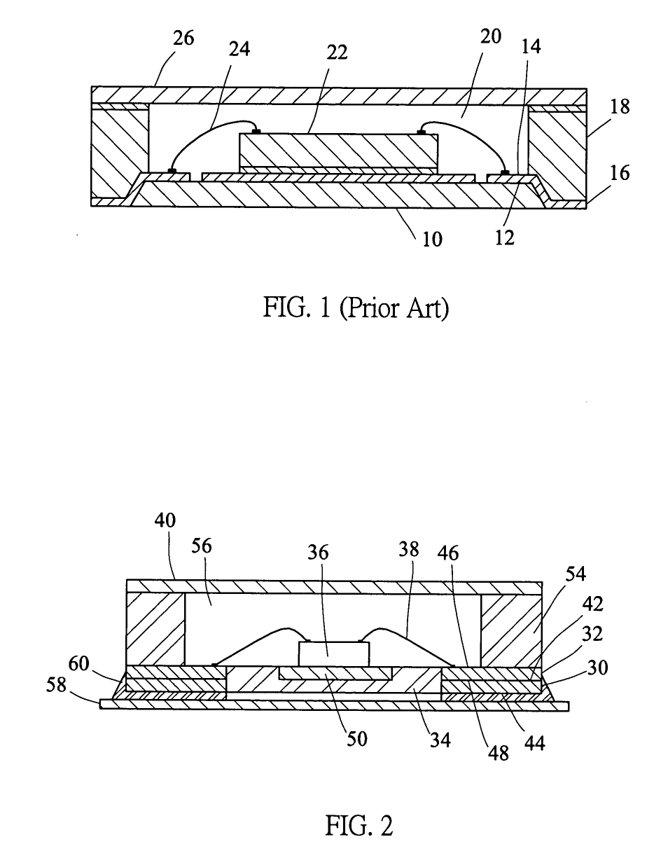

### DETAILED DESCRIPTION OF THE INVENTION

Referring to FIG. 2, an image sensor of the invention includes a plurality of lower metal sheets 30 arranged in an array, a plurality of upper metal sheets 32 arranged in an array, an encapsulant 34, a photosensitive chip 36, a plurality of wires 38, and a transparent layer 40.

Each lower metal sheet 30 has an upper surface 42 and a lower surface 44 mounted to a printed circuit board 58 via solder tin 60 in the SMT process.

Each upper metal sheet 32 has an upper surface 46 and a lower surface 48. A middle board 50 flush with the upper metal sheets 32 is arranged among the upper metal sheets 32. The lower surfaces 48 are stacked on the corresponding upper surfaces 42 of the lower metal sheets 30.

The encapsulant 34 encapsulates the lower metal sheets 30, the upper metal sheets 32 and the middle board 50 with the upper surfaces 46 of the upper metal sheets 32 and an upper surface of the middle board 50 exposed from the encapsulant 34 and with the lower surfaces 44 of the lower metal sheets 30 exposed from the encapsulant 34. A frame layer 54 is formed around the upper surfaces 46 of the upper metal sheets 32 to define a chamber 56 together with the upper metal sheets 32.

The photosensitive chip 36 is arranged on the middle board 50 and located within the chamber 56.

The plurality of wires 38 electrically connect the photosensitive chip 36 to the upper surfaces 46 of the upper metal sheets 32 so as to transfer signals from the photosensitive chip 36 to the upper metal sheets 32.

The transparent layer 40 is a piece of transparent glass arranged on the frame layer 54 of the encapsulant 34 to cover the photosensitive chip 36. Thus, the photosensitive chip 36 may receive optical signals passing through the transparent layer 40.

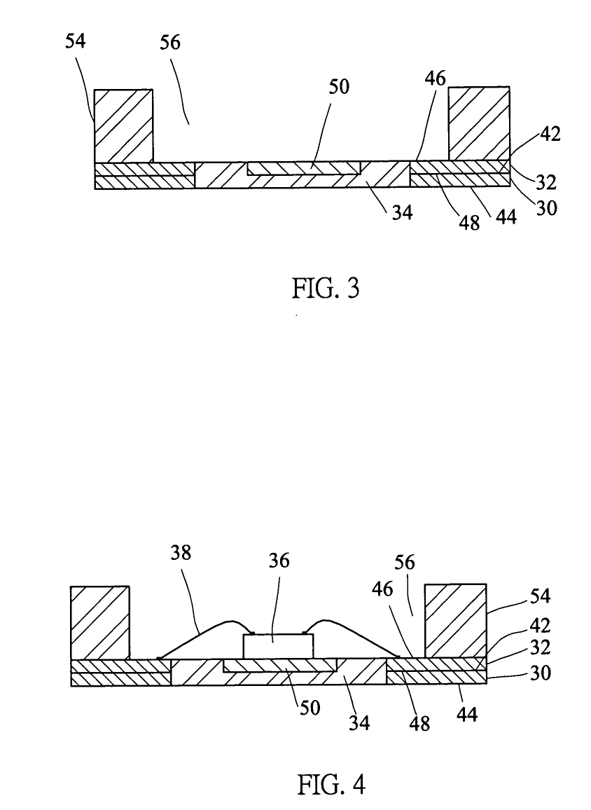

Referring to FIG. 3, a method for packaging an image sensor of the invention includes the steps of:
providing a plurality of lower metal sheets 30 arranged in an array, each of the lower metal sheets 30 having an upper surface 42 and a lower surface 44;
providing a plurality of upper metal sheets 32 arranged in an array, each of the upper metal sheets 32 having an upper surface 46 and a lower surface 48, and providing a middle board 50 arranged among and flush with the upper metal sheets 32, the lower surfaces 48 being stacked on the upper surfaces 42 of the lower metal sheets 30; and
encapsulating the lower metal sheets 30, the upper metal sheets 32 and the middle board 50 using industrial plastic material by way of injection molding, wherein the upper surfaces 46 of the upper metal sheets 32 and an upper surface of the middle board 50 are exposed from the encapsulant 34 and the lower surfaces 44 of the lower metal sheets 30 are exposed from the encapsulant 34, and forming a frame layer 54 around the upper surfaces 46 of the upper metal sheets 32 to define a chamber 56 together with the upper metal sheets 32.

Referring to FIG. 4, the method for packaging the image sensor of the invention further includes the steps of:
mounting a photosensitive chip 36 to the middle board 50 and within the chamber 56;
providing a plurality of wires 38 to electrically connect the photosensitive chip 36 to the upper surfaces 46 of the upper metal sheets 32 so as to transfer signals from the photosensitive chip 36 to the upper metal sheets 32; and
arranging a transparent layer 40, which is a piece of transparent glass, on the frame layer 54 of the encapsulant 34 to cover the photosensitive chip 36 so that the photosensitive chip 36 may receive optical signals passing through the transparent layer 40.

The invention has the following advantages.

1. Since the upper and lower metal sheets 32 and 30 are formed from two flat boards, better smoothness may be obtained. Consequently, the wire bonding process may be easily performed, and the package yield of the product may be improved.

2. Since the combination of the upper and lower metal sheets 32 and 30 is thicker, the solder tin 60 may climb to the upper metal sheets 32 from the lower metal sheets 30 during the SMT process for mounting the image sensor to the printed circuit board 58. Therefore, the package body can be mounted to the printed circuit board 58 with great stability.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. An image sensor to be electrically connected to a printed circuit board, the image sensor comprising:
a plurality of lower metal sheets arranged in an array, each of the lower metal sheets having an upper surface and a lower surface;
a plurality of upper metal sheets arranged in an array, each of the upper metal sheets having an upper surface and a lower surface, the lower surfaces of the upper metal sheets being stacked on the upper surfaces of the lower metal sheets;
an encapsulant for encapsulating the lower metal sheets and the upper metal sheets, wherein the upper surfaces of the upper metal sheets are exposed from the encapsulant, the lower surfaces of the lower metal sheets are exposed from the encapsulant and electrically connected to the printed circuit board, and the encapsulant is formed with a frame layer around the upper surfaces of the upper metal sheets to define a chamber together with the upper metal sheets;
a photosensitive chip arranged within the chamber;
a plurality of wires for electrically connecting the photosensitive chip to the upper surfaces of the upper metal sheets; and
a transparent layer arranged on the frame layer of the encapsulant to cover the photosensitive chip.

2. The image sensor according to claim 1, further comprising a middle board arranged among and flush with the upper metal sheets, and the photosensitive chip being mounted to the middle board.

3. The image sensor according to claim 1, wherein the encapsulant is made of industrial plastic material, and the encapsulant and the frame layer are integrally formed.

4. The image sensor according to claim 1, wherein the transparent layer is a piece of transparent glass.

5. A method for packaging an image sensor, comprising the steps of:
providing a plurality of lower metal sheets arranged in an array, each of the lower metal sheets having an upper surface and a lower surface;
providing a plurality of upper metal sheets arranged in an array, each of the upper metal sheets having an upper surface and a lower surface, the lower surfaces of the upper metal sheets being stacked on the upper surfaces of the lower metal sheets;
providing an encapsulant for encapsulating the lower metal sheets and the upper metal sheets, wherein the upper surfaces of the upper metal sheets are exposed from the encapsulant, the lower surfaces of the lower metal sheets are exposed from the encapsulant and electrically connected to a printed circuit board, and the encapsulant is formed with a frame layer around the upper surfaces of the upper metal sheets to define a chamber together with the upper metal sheets;
arranging a photosensitive chip within the chamber; and
arranging a transparent layer on the frame layer of the encapsulant to cover the photosensitive chip.

6. The method according to claim 5, further comprising:
arranging a middle board among and flush with the upper metal sheets, and the photosensitive chip being mounted to the middle board.

8. The method according to claim 5, wherein the encapsulant and the frame layer are formed from industrial plastic material by way of injection molding.
